(19) United States
(12) Patent Application Publication
(10) Pub. No.: US 2020/0075816 A1
(43) Pub. Date: Mar. 5, 2020

(54) MICRO-LED APPARATUS WITH ENHANCED ILLUMINATION, AND METHOD FOR FORMING SUCH

(71) Applicant: Oregon State University, Corvallis, OR (US)

(72) Inventors: Li-Jing Cheng, Corvallis, OR (US); Akash Kannegulla, Corvallis, OR (US)

(73) Assignee: Oregon State University, Corvallis, OR (US)

(21) Appl. No.: 16/549,933

(22) Filed: Aug. 23, 2019

Related U.S. Application Data
(60) Provisional application No. 62/724,958, filed on Aug. 30, 2018.

(51) Int. Cl. H01L 33/50; H01L 27/15

(52) U.S. Cl. CPC H01L 33/504; H01L 2933/0041; H01L 27/156

(57) ABSTRACT

A light emitting diode (LED) apparatus is described that applies plasmonic nanoparticles to enhance multicolor emitting materials, such as quantum dots (QDs) or fluorophores, in the color conversion layer of micro-LED and suppress the UV transmission. The metal nanoparticles, including but not limited to, aluminum, gold, copper, platinum, and silver have surface plasmon resonances in or close to the wavelength of excitation light or the wavelength of emission colors. UV or blue excitation over a color conversion layer formed by the mixture of emitting materials and scattering nanoparticles leads to enhancement of emission and thus increase in their quantum efficiency. An excitation filter is also used with in the LED apparatus to block the transmission of UV or blue excitation.

### CLAIM FOR PRIORITY

This application claims priority to U.S. Provisional Patent Application No. 62/724,958, filed on 30 Aug. 2018, titled “MICRO-LED DEVICE,” and which is incorporated by reference in its entirety.

### BACKGROUND

Micro light emitting diode (micro-LED) display is emerging as a candidate to drive a new generation of display technology. LED based light sources are also widely used in lighting applications. It remains a challenge to develop cost-effective color conversion micro-LED technologies with enhanced light emission efficiency and minimized excitation light leakage through its color conversion layer.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a three-dimensional (3D) micro-LED array where each LED includes an enhanced color conversion structure over excitation LED structure, in accordance with some embodiments.

FIG. 1B illustrates a cross-section of a micro-LED of FIG. 1A, in accordance with some embodiments.

FIG. 2A illustrates a 3D micro-LED array where each LED includes a color conversion structure over excitation LED structure and below an excitation filter structure, in accordance with some embodiments.

FIG. 2B illustrates a cross-section of a micro-LED of FIG. 2A, in accordance with some embodiments.

FIG. 3A illustrates a 3D micro-LED array where each LED includes an enhanced color conversion structure over excitation LED structure and below an excitation filter structure, in accordance with some embodiments.

FIG. 3B illustrates a cross-section of a micro-LED of FIG. 3A, in accordance with some embodiments.

FIGS. 4A-E illustrate cross-sections of color conversion LED displays that use enhanced color conversion structures and excitation filter structures in various configurations, respectively, in accordance with some embodiments.

FIG. 5 illustrates a method of forming a micro-LED, in accordance with some embodiments.

FIG. 6 illustrates a method of forming a micro-LED, in accordance with some embodiments.

FIG. 7A illustrates a micro-LED chip with and without nanoparticles indicating the presence of leakage and an eventual emission enhancement after adding nanoparticles, respectively, in accordance with some embodiments.

FIG. 7B illustrates a plot showing normalized measured absorbance spectra of 30 nm silver nanoparticles dispersed in DI (deionized) water and embedded in a PVP (polyvinylpyrrolidone) thin film, in accordance with some embodiments.

FIG. 8A illustrates a plot showing transmission and enhancement factors of carbon dot (CD) emissive layer while increasing the Ag nanoparticle concentration, in accordance with some embodiments.

FIG. 8B illustrates a spectra plot showing the transmission in UV regime and photoluminescence of CD at increasing Ag concentrations, in accordance with some embodiments.

FIG. 9A illustrates a bird-eye image of GaN-based UV LED chip with nine LEDs of dimensions 1 mm×1 mm, in accordance with some embodiments.

FIG. 9B illustrates a bird-eye image of an enhanced micro-LED with zero UV leakage, made over the center UV LED, in accordance with some embodiments.

FIG. 9C illustrates a microscopic image of a GaN-based UV LED without emissive layer.

FIG. 9D illustrates a microscopic image of an enhanced micro-LED with zero UV leakage, made over the center UV LED and an emissive layer, in accordance with some embodiments.

FIG. 10 illustrates CIE chromaticity diagram of the excitation and emission light showing the suitability of CD based micro-LED for display technology, in accordance with some embodiments.

### DETAILED DESCRIPTION

Gallium-nitride-based (GaN) light-emitting diodes (LEDs) have attracted much attention because of their low power consumption, long device lifetime, low cost, and high brightness for applications such as backlight units in liquid crystal displays and visible light communications. Recently, GaN based backlight LEDs are extensively used as promising candidates for color conversion micro-LED display technology. The color conversion micro-LED display carry an advantage of photoluminescence (PL), which is the emission obtained with an electromagnetic wave input rather than electrical input utilized for organic LED (OLED) and quantum-dot (QLED) display technologies. This leads to a very large color gamut thus pushing the envelope of display technology.

Semiconductor quantum dots (QDs) and fluorophores have been applied for color conversion micro-LEDs for reduction in optical crosstalk and control of excitation light leakage. However, QD or fluorophore based micro-LED needs additional processing of depositing the dielectric multi-layers, thus creating Bragg reflectors, which has a high reflectivity at UV regime and a large transmission at visible wavelengths.

Color conversion micro-LED based on quantum dots (QDs) and UV micro-LED utilize the photoluminescence (PL) of UV-excited QDs to achieve large coverage of color gamut and low power consumption. QDs include particles of various materials, including semiconductors, metals, inorganic materials, or organic materials characterized by a size regime about several or tens of nanometers such that their optical and electronic properties deviate from the bulk properties of the same material. As briefly discussed in the background section, there is high demand to develop cost-effective technologies to enhance QD emission and minimize UV light leakage through the QD.

Some embodiments apply UV plasmonic nanoparticles to enhance multicolor QDs in the emitting layer of micro-LED and suppress the UV transmission. The metal nanoparticles, including but not limited to, aluminum, gold, copper, platinum, and silver have surface plasmon resonances in or close to the UV range. UV excitation over an emitting layer formed by the mixture of QDs and metal nanoparticles leads to excitation enhancement of QDs and thus increase in their quantum efficiency.

In one example, emitting layers fabricated by dispersing a mixture of 80 nm aluminum nanoparticles and QDs at various ratios obtain a maximum enhancement factor of approximately 5. The term, “enhancement factor” is generally defined as a ratio of light intensity emitted by a color conversion layer with and without the presence of scattering particles. On the other hand, in another example with a QD emitting layer comprising 30 nm silver nanoparticles achieve a maximum enhancement factor of approximately 7. Both enhancement factors are larger than enhancement factors for traditional micro-LEDs. The metal nanoparticles also absorb the UV excitation and reduce the leakage of UV light that is used for user's safety. The enhanced QD PL is a result of excitation enhancement or Purcell effect.

In one exemplary embodiment, carbon dot (CD) emissive layers are used with silver (Ag) plasmonic nanoparticles to enhance the PL of CDs while minimizing the leakage of excitation light. The emissive layer may include any QD material as is known in the art. Conventional micro-LEDs lack PL enhancement. The fluorescence emission is improved by incorporating, for example, 30 nm Ag nanoparticles that absorbs the excitation light and enhance the PL at same time.

The PL enhancement follows the excitation enhancement route. For example, a 400 nm light excited using GaN backlight LED excites the CDs and also couples with the Ag nanoparticles. In this example, the localized surface plasmons created through the 400 nm excitation acts as an additional source for CDs, leading to an enhanced emission. At same time, due to the formation of surface plasmons, the additional light is coupled with nanoparticles and minimizes its leakage to the far-field. In the absence of plasmonic nanoparticles, the additional excitation from the source may leak out of the CD film leading to leakage and poor image quality. Nanoparticles such as Ag (silver) serve as excellent blocking agents and lead to a broadband enhancement of CDs. This technique offers a low-cost and effective approach to improve the performance of micro-LED display. This technique is applicable to any emissive materials for illumination enhancement. Other technical effects will be evident from the various embodiments and figures.

The embodiments of the disclosure will be understood more fully from the detailed description given below and from the accompanying drawings of various embodiments of the disclosure, which, however, should not be taken to limit the disclosure to the specific embodiments, but are for explanation and understanding only.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one light, current signal, voltage signal, optical, electromagnetic signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions.

It is pointed out that those elements of the figures having the same reference numbers (or names) as the elements of any other figure can operate or function in any manner similar to that described, but are not limited to such.

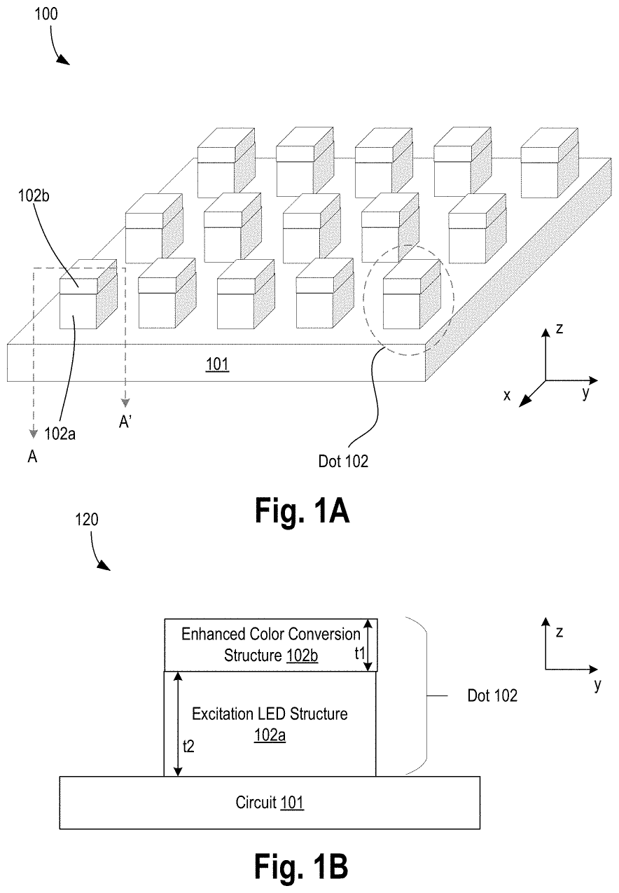

FIG. 1A illustrates three-dimensional (3D) micro-LED array 100 where each LED includes an enhanced color conversion structure over excitation LED structure, in accordance with some embodiments. Array 100 comprises a substrate or base that includes circuitry to control each LED of the array. The circuitry may include current and voltage sources that provide the bias and current to the LED that is to be excited. The circuitry can include LED drivers.

In this example, a 5×3 array is illustrated. However, micro-LED array 100 can have any number of LEDs arranged in any order on substrate 101. Array 100 can be used as a light source (e.g., LED bulb) or in a display (e.g., phone or TV display). Each LED 102 is a dot that comprises at least two structures—excitation LED structure 102a and enhanced color conversion structure 102b. FIG. 1B illustrates cross-section 120 of a micro-LED of FIG. 1A, in accordance with some embodiments.

In some embodiments, excitation LED 102a has a wavelength in blue or UV, or other wavelengths that can excite enhanced color conversion layer 102b. In some embodiments, the thickness t2 of the excitation LED structure 102a in a range of 50 nm (nanometers) to 1 mm (millimeter). In some embodiments, enhanced color conversion structure 102b comprises a mixture of emitting materials and scattering particles that can be embedded in a host medium. In some embodiments, the emitting materials can be carbon nanoparticles, organic/inorganic fluorophores, semiconductor nanoparticles, or perovskites. Organic or inorganic fluorophores are mostly small molecules while perovskites are particles with the size ranging from nanoparticle to flakes. All of them can be used in a form of dried powder or powder dispersed in a solution. It is similar to the carbon dots and quantum dots presented here in terms of how they are used. In some embodiments, if the emitting material is embedded in a host material, the concentration of the emitting material in the host medium can be at least 10⁻⁴ wt %. In some embodiments, the scattering particles can be metal particles and oxide particles.

In some embodiments, the metal particles include one or more of: silver, gold, aluminum, copper, platinum, chromium, nickel, or their alloys. In some embodiments, the oxide particles comprise metal oxides, which include one or more of: tin oxide, zinc oxide, titanium oxide, indium oxide, or their combination. In some embodiments, the host medium can be made of transparent materials, including polymer (polyvinylpyrrolidone, polydimethylacrylamide, polyacrylate, polymethacrylate, polyvinyl alcohol, and polyvinyl acetate), silicon oxide, and silicon nitride. In some embodiments, thickness t1 of enhanced color conversion structure is in a range of 50 nm (nanometers) to 2 mm (millimeter). In some embodiments, the size of the scattering particles can range from 5 nm to 1 μm (micrometer). In some embodiments, the density of the scattering particles in the enhanced color conversion structure 102b can range from 10⁸ to 10¹³ particles/cm³.

The enhanced color conversion structure 102b itself can be applied to form a color converted LED display or a micro-LED display. The display utilizes an array of excitation LEDs, which could be UV or blue monochromic LEDs, to excite the color conversion structure 102b to generate red, green, and blue colors. In some embodiments, if a monochromic blue LED array is used, there may be no need for the blue color conversion layer for the blue pixels.

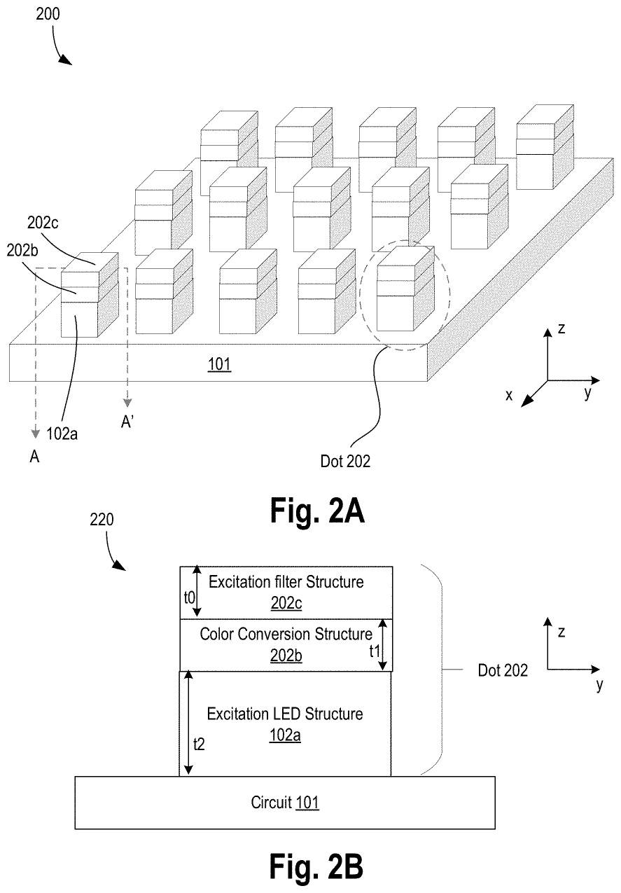

FIG. 2A illustrates a 3D micro-LED array 200 where each LED includes a color conversion structure over excitation LED structure and below an excitation filter structure, in accordance with some embodiments. FIG. 2B illustrates cross-section 220 of a micro-LED of FIG. 2A, in accordance with some embodiments. Compared to array 100, here each LED dot 202 comprises excitation LED structure 102a, color conversion structure 202b, and excitation filter structure 202c.

In some embodiments, color conversion structure 202b is a conventional color conversion structure 202b which comprises emitting material that is embedded in a host medium. Thickness t1 of color conversion structure 202b is in a range of 50 nm (nanometers) to 2 mm (millimeter). To suppress the leaking UV light through color conversion structure 202b, an excitation filter structure 202c is provided over color conversion structure 202b. In some embodiments, thickness t0 of excitation filter structure 202c is in a range of 50 nm to 2 mm.

In some embodiments, excitation filter structure 202c comprises a mixture of particles embedded in a host medium. In some embodiments, the particles include one or more of: silver, gold, aluminum, copper, platinum, chromium, nickel, or their alloys. In some embodiments, the oxide particles include one or more of: metal oxides, such as tin oxide, zinc oxide, titanium oxide, or indium oxide. In some embodiments, the host medium includes one or more of: transparent materials, including polymer (polyvinylpyrrolidone, polydimethylacrylamide, polyacrylate, polymethacrylate, polyvinyl alcohol, and polyvinyl acetate), silicon oxide, or silicon nitride. The size of the scattering particles can range from 2 nanometers to 1 micrometer. The density of the scattering particles in the excitation filter layer can range from 10⁸ to 10¹³ particles/cm³.

In some embodiments, excitation filter structure can be designed to block a blue or UV excitation light depending on the choice of metal particles. In some embodiments, excitation filter structure 202c is used with the conventional color conversion structure 202b for the micro-LED display application. In some embodiments, the display utilizes an array of excitation LEDs, which could be UV or blue monochromic LEDs, to excite the color conversion layer to generate red, green, and blue colors. In some embodiments, if a monochromic blue LED array is used, there may be no need for the blue color conversion layer and the excitation filter layer for the blue pixels.

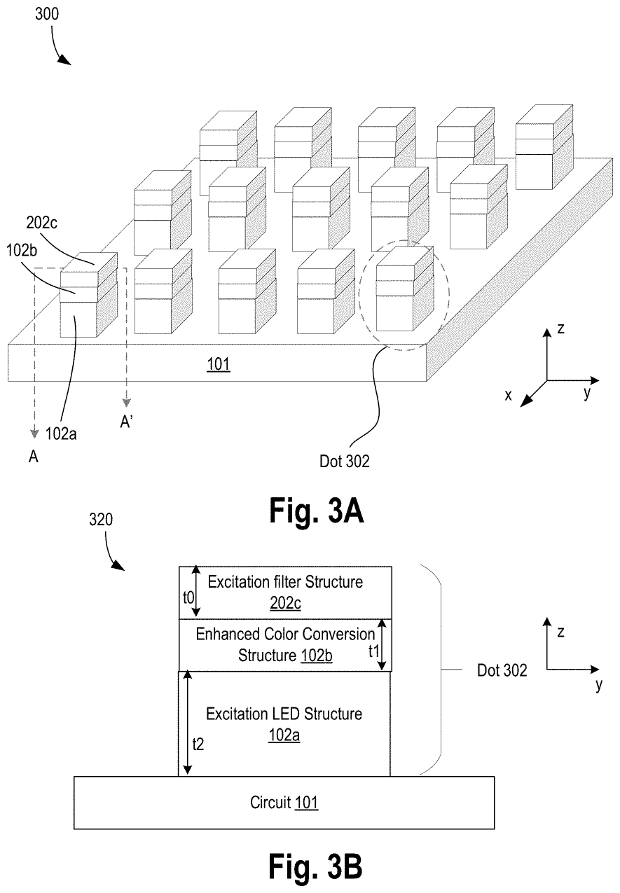

FIG. 3A illustrates 3D micro-LED array 300 where each LED includes an enhanced color conversion structure over excitation LED structure and below an excitation filter structure, in accordance with some embodiments. FIG. 3B illustrates cross-section 320 of a micro-LED of FIG. 3A, in accordance with some embodiments. Compared to array 200, here each LED dot 302 comprises excitation LED structure 102a, enhanced color conversion structure 102b, and excitation filter structure 202c. Materials for excitation LED structure 102a, enhanced color conversion structure 102b, and excitation filter structure 202c are described with reference to FIGS. 1-2, and other embodiments.

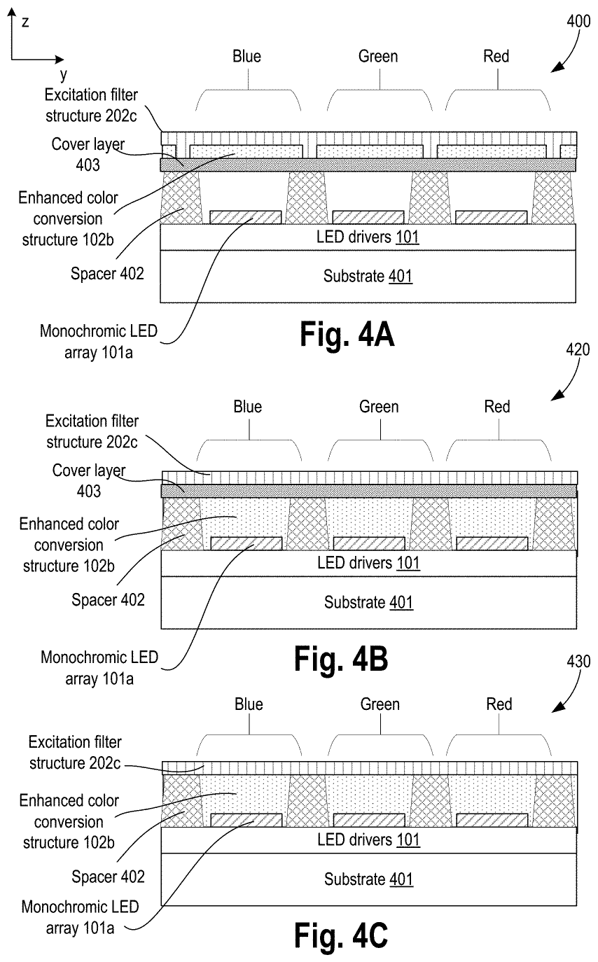

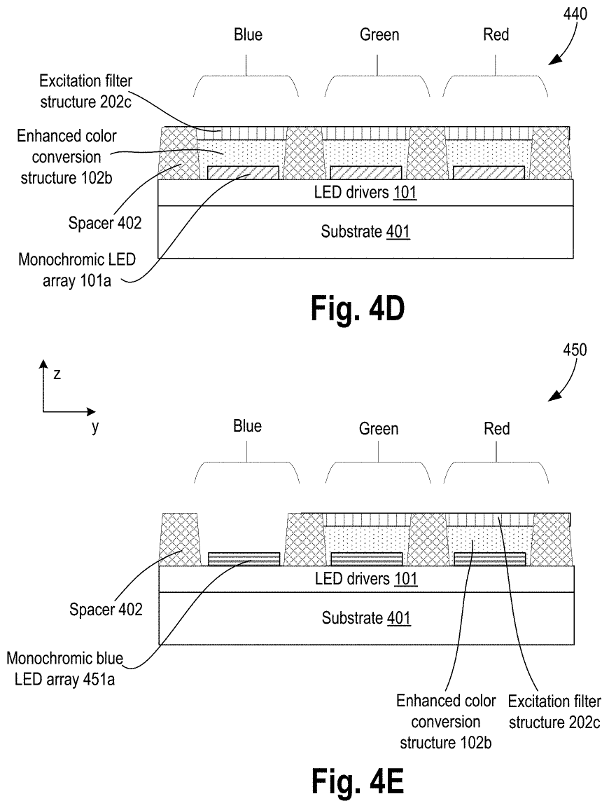

The enhanced color conversion structure itself or its combination with the excitation filter structure can be applied to form a color conversion LED display or a micro-LED display. In some embodiments, the excitation filter structure is used with the conventional color conversion layer for the micro-LED display application. FIGS. 4A-E show the structures of the display, in accordance with some embodiments.

FIGS. 4A-E illustrate cross-sections 400, 420, 430, 440, and 450, respectively, of color conversion LED displays that use enhanced color conversion structures and excitation filter structures in various configurations, in accordance with some embodiments.

The display utilizes an array of excitation LEDs, which could be UV or blue monochromic LEDs, to excite the color conversion layer to generate red, green, and blue colors. Cross-section 400 illustrates blue, green, and red LED arrays that are formed over a layer of LED drivers 101, where LED drivers 101 are disposed on substrate 401 (e.g., SiO² and semiconductor). In various embodiments, each UV excitation LED array 101a is separated by spacers 402. Spacers 402 include any suitable insulative material such as polymer and SiO². In some embodiments, cover layer 403 is provided which is formed over spacers and provides a foundation for the enhanced color conversion structure 102b. The cover layer 403 seals the enhanced conversion layer 102b that is filled between the spacers 402. For each color, a separate enhanced color conversion structure 102b is formed. Excitation filter structure 201c is then formed over the enhanced color conversion structures 102b such that it covers the whole conversion structure 102b.

Cross-section 420 is similar to cross-section 400 except that excitation filter structure 202c is directly adjacent to cover layer 403, and enhanced color conversion structures are formed between spacers 402 and below cover layer 403. Placing color conversion structure between spacers can reduce the interference of excitation between neighboring pixels.

Cross-section 430 is similar to cross-section 420 but without cover layer 403. Here, excitation filter structure 202c is formed directly adjacent to spacers 402 and enhanced color conversion structures 102b. The structure without the cover layer 403 allows formation of non-flat enhanced color conversion structure and excitation filter structure.

Cross-section 440 is similar to cross-section 430 but for the configuration of excitation filter structure 202c. Here, excitation filter structure 202c is between spacers and above and adjacent to corresponding enhanced color conversion structures. In some embodiments, for each color, a separate excitation filter is formed to accommodate different levels of excitation leakage through different color conversion structures. Red, green, and blue color conversion layers yield different levels of UV leakage. In some embodiments, separated distribution of the excitation filters allow for assigning different excitation filters, which contain different scattering particle concentration, on different color pixels.

Cross-section 450 is similar to cross-section 440 but for using monochromic blue LED array 451a for the blue light. As such, there is no need for blue color conversion layer and associated excitation filter layer for the blue pixels.

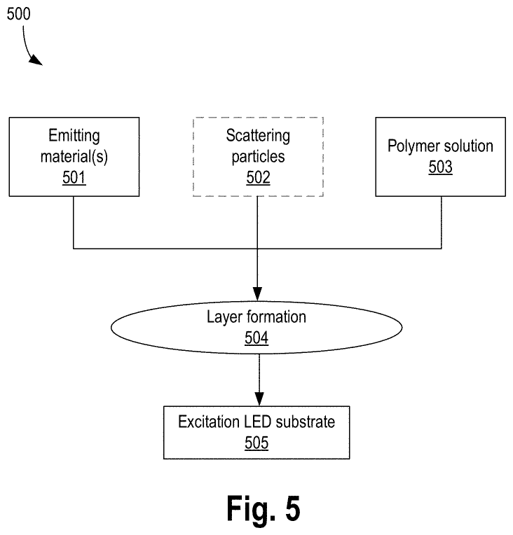

FIG. 5 illustrates flowchart 500 showing a method of forming a micro-LED, in accordance with some embodiments. While the blocks in the flowchart are shown in a particular order, the order can be changed. For example, some bocks or operations can be performed before others while some can be performed in parallel.

One way to form the enhanced color conversion structure 102b or the excitation filter structure 202c is by delivering a solution mixture, which contains the emitting materials 501 and/or scattering particles 502 and polymer solution 503, to a substrate 101/505. Polymer 503 can be polyvinylpyrrolidone, polydimethylacrylamide, polyacrylate, polymethacrylate, poly(methyl methacrylate), polyvinyl alcohol, and/or polyvinyl acetate. Processes 504 for the layer formation include spin-coating, stamping, screen-printing, inkjet printing, and plotting, for example.

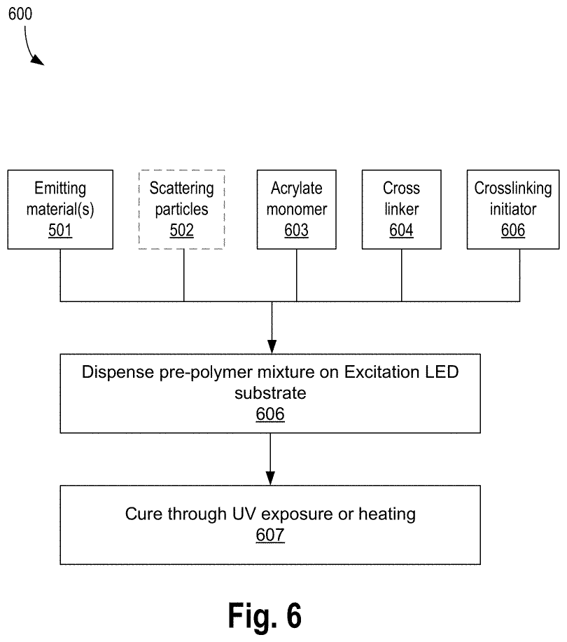

FIG. 6 illustrates flowchart 600 showing a method of forming a micro-LED, in accordance with some embodiments. While the blocks in the flowchart are shown in a particular order, the order can be changed. For example, some bocks or operations can be performed before others while some can be performed in parallel.

The enhanced color conversion structure 102b or the excitation filter structure 202c is by delivering a solution mixture (i.e., prepolymer mixture) which contains the emitting materials 501 and/or scattering particles 502, acrylate monomer solution 603, cross-linker 604, and crosslinking initiator 606 to a substrate 101. For example, prepolymer solution is prepared by mixing the emitting materials and/or scattering particles with a mixture of an acrylate monomer, cross-linker and crosslinking initiator in an optional solvent. The acrylate monomer includes one or more of: methyl acrylate, N,N-dimethyl acrylamide, methacrylamide, or methyl methacrylate. The cross-linker includes one or more of: ethylene glycol diacrylate, polyethylene glycol diacrylate, divinylbenzene, pentaerythritol triacrylate, or trimethylolpropane trimethacrylate. The crosslinker includes one or more of: 2-hydroxy-4-(2-hydroxyethoxy)-2-methylpropiophenone, 2,2′ azobis(2-methylpropionitrile), benzophenone, or azobisisobutyronitrile.

In this method, at block 606 prepolymer mixture is distributed on substrate 101. In some embodiments, the prepolymer solution is distributed to the substrate by the process, such as spin-coating, stamping, screen printing, inkjet printing, and plotting. At block 607, the distributed prepolymer material is cured to solidify the coating through light exposure or heating.

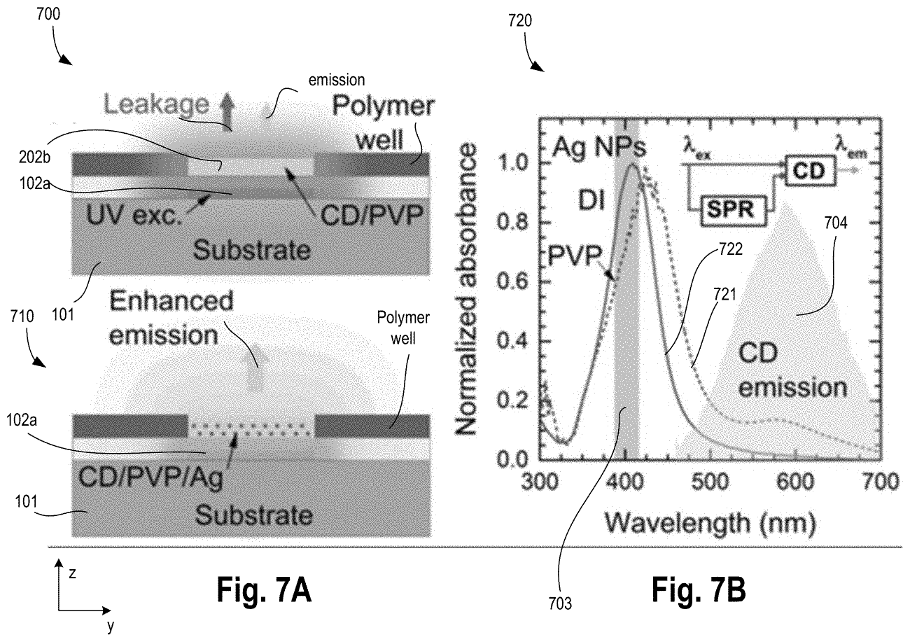

FIG. 7A illustrates micro-LED chips 700 and 710 with and without nanoparticles indicating the presence of leakage and an eventual emission enhancement after adding nanoparticles, respectively, in accordance with some embodiments. Chip 700 illustrates the case where traditional color conversion structure 202b results in leakage along with emission of light from excitation LED structure 102a. Conversely, chip 710 illustrates the case of enhanced emission when color conversion structure is mixed with metal particles such as Ag. In this case, leakage is removed too.

Here, GaN-based LED is encapsulated with polymer layer followed by formation of silicon-based polymer well for drop casting of the emissive layer. In this example, GaN based UV LED chip with emission wavelength of 400 nm is encapsulated by a transparent polymer, and utilized as an excitation source 102a for micro-LED. An optically insulating silicone polymer well is attached over the excitation source followed by drop casting the emission layer for further measurements using a spectrometer.

In this example, CDs are dispersed in 300 mg/mL polyvinylpyrrolidone (PVP) in ethanol for drop casting in the silicon polymer well to form an approximately 400 μm thick film. Aside from PVP, other thermoplastic materials also work, including but not limited to ethylene vinyl alcohol, fluoroplastics such as polytetrafluoroethylene, fluoro ethylene propylene, perfluoroalkoxyalkane, chlorotrifluoroethylene, ethylene chlorotrifluoroethylene, or ethylene tetrafluoroethylene, ionomer, polyacrylate, polybutadiene, polybutylene, polyethylene, polyethylenechlorinates, polymethylpentene, polypropylene, polystyrene, polyvinylchloride, polyvinylidene chloride, polyamide, polyamide-imide, polyaryletherketone, polycarbonate, polyketone, polyester, polyetheretherketone, polyetherimide, polyethersulfone, polyimide, polyphenylene oxide, polyphenylene sulfide, polyphthalamide, polysulfone, or polyurethane.

Due to the transparency of the PVP film, there exists a strong transmission through it leading to a heavy leakage and a relatively negligible emission of CDs as shown in chip 700. Ag nanoparticles are introduced to minimize the leakage and enhance the emission simultaneously as shown in chip 710. This mechanism of CD enhancement follows the excitation rate enhancement as reported in the past. The inset of FIG. 7B shows the block diagram of the CD enhancement. The UV source from the GaN chip acts as an excitation for the CDs and excites the surface plasmon on Ag nanoparticles to provide additional source of energy for CD enhancement. Since the absorption of Ag nanoparticles lies in the UV region, it blocks the UV light from leaking through the film, in accordance with some embodiments.

The carbon dots can be synthesized using, for example, 500 mg of citric acid and 1 g of urea dissolved in 10 mL ethanol solution. The solution is then transferred into a 30 mL teflon-line stainless steel autoclave. The sealed autoclave is heated at 180° C. for 8 hours, for example. Then the as obtained CDs are purified by ethanol water solution, and the precipitates are collected and re-dispersed in DI water. The emission of carbon dots is indicated in figure FIG. 7B.

FIG. 7B illustrates plot 720 showing normalized measured absorbance spectra of 30 nm silver nanoparticles dispersed in DI (deionized) water and embedded in a PVP (polyvinylpyrrolidone) thin film, in accordance with some embodiments. Ag nanoparticles (Ag NPs) are synthesized based on chemical reduction method. Two reductants sodium borohydride (NaBH₄) and trisodium citrate (TSC) can be used as primary reductant and stabilizing agents, respectively. One example procedure is described here. The procedure is: 48 mL of aqueous solution containing 1 mM of NaBH₄ and 4 mM of TSC is stirred at 60° C. for 30 min. Then, 2 mL aqueous silver nitrate (AgNO₃) solution (4 mM) is added drop-wise while the temperature is raised to 90° C. Within 3 minutes, for example, the color of solution starts changing from transparent to dark yellow. The reaction can be stopped and the beaker allowed to cool down in the dark at room temperature followed by purification with centrifuge. The Ag NP suspension is centrifuged three times (e.g., 9000 rpm, 10 min) and the obtained powder is suspended in DI water and stored at 4° C. in dark for future use. The obtained Ag NPs show the absorbance spectra peaking at 400 nm, thus estimating its size to be 30 nm. After they are dispersed in CD polymer solution the resonance spectra shift peaking at 420 nm wavelength. The faded region 703 indicates the excitation range and the faded spectra 704 indicates the emission of CDs.

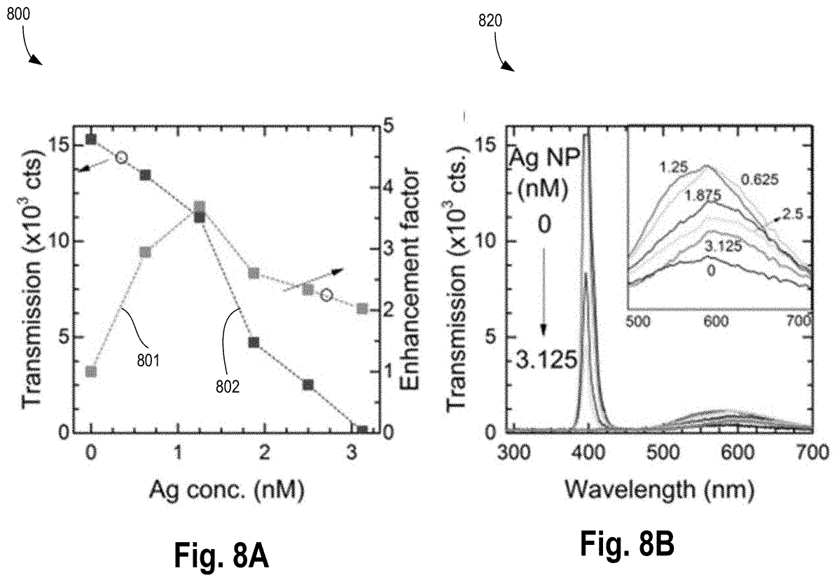

FIG. 8A illustrates plot 800 showing transmission and enhancement factors of carbon dot (CD) emissive layer while increasing the Ag nanoparticle concentration, in accordance with some embodiments. Plot 800 shows a working of CD enhancement and UV leakage control. As the concentration of Ag nanoparticles in the film is increased from 0 to 3.125 nM, a maximum enhancement of 3.68 times is observed at 1.25 nM of Ag nanoparticles. As the nanoparticle concentration is increased even more, the leakage of UV reduces to zero while the emission enhancement of two times is still observed. In this micro-LED, the PL spectrum in the solution and on the UV chip is same with an additional 2-fold enhancement. In various embodiments, the use of surface plasmonic nanoparticles reduces the UV leakage to zero (or near zero).

FIG. 8B illustrates spectra plot 820 showing the transmission in UV regime and photoluminescence of CD at increasing Ag concentrations, in accordance with some embodiments. Plot 820 shows the measured PL spectra of micro-LED at various Ag nanoparticle concentrations. As the concentration increases, the intensity of UV wavelength reduces while a different behavior exists for CD enhancement. The CD enhancement factor is determined by a ratio of CD emission with and without Ag nanoparticles. At first, the enhancement factor increases because the Ag nanoparticles are too far away for enhancement to occur, and after certain concentration, the enhancement factor reduces from 3.68 to 2 times due to the blocking of emission light as result of excessive metal nanoparticles in the film. However, the metal nanoparticles hold the capacity of broadband enhancement and reduce the UV leakage, thus avoiding the additional processing of filters/Bragg's reflector deposition.

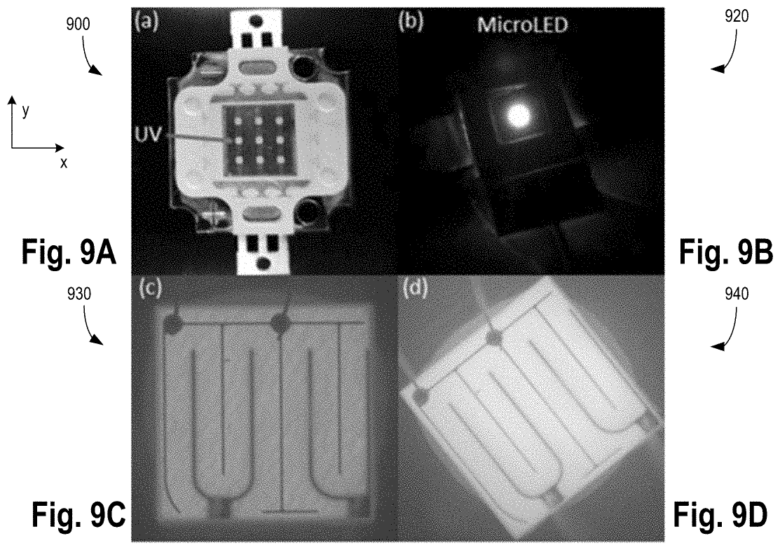

FIG. 9A illustrates bird-eye image 900 of GaN-based UV LED chip with 9 LEDs of dimensions 1 nm×1 mm, in accordance with some embodiments.

FIG. 9B illustrates microscopic image 920 of an enhanced micro-LED with zero UV leakage, made over the center UV LED, in accordance with some embodiments.

FIG. 9C illustrates bird-eye image 930 of UV LED without emissive layer, in accordance with some embodiments.

FIG. 9D illustrates microscopic image 920 an enhanced micro-LED with zero UV leakage, made over the center UV LED and without emissive layer, in accordance with some embodiments. Such a bright emission by an excitation source of 1 mm×1 mm shows the efficiency of emissive material utilized here and it is fit for display technology.

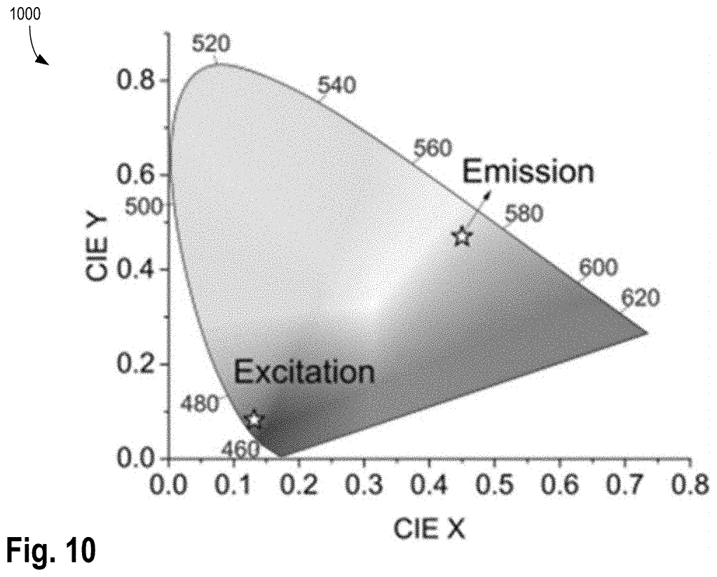

FIG. 10 illustrates CIE chromaticity diagram 1000 of the excitation and emission light showing the suitability of CD based micro-LED for display technology, in accordance with some embodiments.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The following examples are provided with reference to various embodiments.

### Example 1

A light-emitting diode (LED) comprising: a first structure comprising an excitation material; and a second structure adjacent to the first structure, wherein the second structure comprises an enhanced color conversion material, wherein the enhanced color conversion material includes a mixture of an emitting material and a scattering material.

### Example 2

The LED of example 1, wherein the emitting material includes one or more of: carbon nanoparticles, organic fluorophores, inorganic fluorophores, semiconductor nanoparticles, or perovskites.

### Example 3

The LED of example 2, wherein the scatting material includes one or more of: metal particles or oxide particles.

### Example 4

The LED of example 3, wherein the metal particles include one or more of: Ag, Au, Al, Cu, Pt, Cr, Ni, or their alloys.

### Example 5

The LED of example 3, wherein the oxide particles include one or more of: tin oxide, zinc oxide, titanium oxide, or indium oxide.

### Example 6

The LED of example 1, wherein the excitation material includes one of blue LED material or ultraviolet (UV) LED material.

### Example 7

The LED of example 1, wherein the enhanced color conversion material is embedded in a host material, which includes one or more of: polymer, silicon oxide, or silicon nitride.

### Example 8

The LED of example 7, wherein the polymer includes one or more of: polyvinylpyrrolidone, polydimethylacrylamide, polyacrylate, polymethacrylate, polyvinyl alcohol, or polyvinyl acetate.

### Example 9

The LED of example 1 comprises circuitry coupled to the first structure to provide current to excite the excitation filter material.

### Example 10

The LED of example 1 comprises a third structure adjacent to the second structure, wherein the third structure comprises an excitation filter material.

### Example 11

The LED of example 10, wherein the excitation filter material includes particles in a host medium, wherein the particles include one or more of: Ag, Au, Al, Cu, Pt, Cr, Ni, or their alloys.

### Example 12

The LED of example 11, wherein the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate.

### Example 13

The LED of example 11, wherein the excitation filter material has a thickness in a range of 50 nanometers to 2 millimeters.

### Example 14

The LED of example 1, wherein the enhanced color conversion material has a thickness in a range of 50 nanometers to 2 millimeters.

### Example 15

The LED of example 1, wherein the excitation material has a wavelength in blue or ultraviolet wavelength.

### Example 16

A light-emitting diode (LED) apparatus comprising: a structure comprising circuitry; and an array of LEDs on the structure, wherein the array is coupled to the structure, wherein the circuitry is to provide current to individual LED of the array, and wherein an individual LED of the array comprises: a first structure comprising excitation material; a second structure adjacent to the first structure, wherein the second structure comprises a color conversion material; and a third structure adjacent to the second structure, wherein the third structure comprises an excitation filter material.

### Example 17

The LED apparatus of example 16, wherein the excitation filter material comprises: particles in a host medium, wherein the particles include one or more of: Ag, Au, Al, Cu, Pt, Cr, Ni, or their alloys, and wherein the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate.

### Example 18

The LED apparatus of example 15, wherein the excitation material has a wavelength in blue or ultraviolet wavelength.

### Example 19

A light-emitting diode (LED) comprising: a first structure to generate excitation light including ultraviolet (UV) light; a second structure adjacent to the first structure, wherein the second structure is to enhance color of the excitation light; and a third structure adjacent to the second structure, wherein the third structure is to filter the UV light and pass the color enhanced excitation light through.

### Example 20

The LED of example 19, wherein: the third structure comprises excitation filter material comprises: particles in a host medium; the particles include one or more of: Ag, Au, Al, Cu, Pt, Cr, Ni, or their alloys; the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate; second structure comprises an enhanced color conversion material, wherein the enhanced color conversion material includes a mixture of an emitting material and a scattering material; the emitting material includes one or more of: carbon nanoparticles, organic fluorophores, inorganic fluorophores, semiconductor nanoparticles, or perovskites. In some embodiments, the scatting material includes one or more of: metal particles or oxide particles; the metal particles include one or more of: Ag, Au, Al, Cu, Pt, Cr, Ni, or their alloys; and the oxide particles include one or more of: tin oxide, zinc oxide, titanium oxide, or indium oxide.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

We claim:

1. A light-emitting diode (LED) comprising:
a first structure comprising an excitation material; and
a second structure adjacent to the first structure, wherein the second structure comprises an enhanced color conversion material, wherein the enhanced color conversion material includes a mixture of an emitting material and a scattering material.

2. The LED of claim 1, wherein the emitting material includes one or more of: carbon nanoparticles, organic fluorophores, inorganic fluorophores, semiconductor nanoparticles, or perovskites.

3. The LED of claim 1, wherein the scatting material includes one or more of: metal particles or oxide particles.

4. The LED of claim 3, wherein the metal particles include one or more of: Ag, Au, Al, Cu, Pt, Cr, Ni, or their alloys.

5. The LED of claim 3, wherein the oxide particles include one or more of: tin oxide, zinc oxide, titanium oxide, or indium oxide.

6. The LED of claim 1, wherein the excitation filter material includes one of blue LED material or ultraviolet (UV) LED material.

7. The LED of claim 1, wherein the emitting or scattering material is embedded in a host material, wherein the host material includes one or more of: polymer, silicon oxide, or silicon nitride.

8. The LED of claim 7, wherein the polymer includes one or more of: polyvinylpyrrolidone, polydimethylacrylamide, polyacrylate, polymethacrylate, polyvinyl alcohol, or polyvinyl acetate.

9. The LED of claim 1 comprises circuitry coupled to the first structure to provide current to excite the excitation material.

10. The LED of claim 1 comprises a third structure adjacent to the second structure, wherein the third structure comprises an excitation filter material.

11. The LED of claim 10, wherein the excitation filter material includes particles in a host medium, wherein the particles include one or more of: Ag, Au, Al, Cu, Pt, Cr, Ni, or their alloys.

12. The LED of claim 11, wherein the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate.

13. The LED of claim 11, wherein the excitation filter material has a thickness in a range of 50 nanometers to 2 millimeters.

14. The LED of claim 1, wherein the enhanced color conversion material has a thickness in a range of 50 nanometers to 2 millimeters.

15. The LED of claim 1, wherein the excitation material has a wavelength in blue or ultraviolet wavelength.

16. A light-emitting diode (LED) apparatus comprising:
a structure comprising circuitry; and
an array of LEDs on the structure, wherein the array is coupled to the structure, wherein the circuitry is to provide current to individual LED of the array, and wherein an individual LED of the array comprises:
a first structure comprising excitation material;
a second structure adjacent to the first structure, wherein the second structure comprises a color conversion material; and
a third structure adjacent to the second structure, wherein the third structure comprises an excitation filter material.

17. The LED apparatus of claim 16, wherein the excitation filter material comprises: particles in a host medium, wherein the particles include one or more of: Ag, Au, Al, Cu, Pt, Cr, Ni, or their alloys, and wherein the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate.

18. The LED apparatus of claim 16, wherein the excitation material has a wavelength in blue or ultraviolet wavelength.

19. A light-emitting diode (LED) comprising:
a first structure to generate excitation light;
a second structure adjacent to the first structure, wherein the second structure is to enhance color of the excitation light to generate a color enhanced light emission; and
a third structure adjacent to the second structure, wherein the third structure is to filter one of blue or UV excitation light and pass the color enhanced light emission.

20. The LED of claim 19, wherein:
the third structure comprises excitation filter material which comprises: particles in a host medium;
the particles include one or more of: Ag, Au, Al, Cu, Pt, Cr, Ni, or their alloys;
the host medium includes one or more of: polymer, silicon oxide, or silicon nitride, and wherein the polymer includes one or more of: polyvinylpyrrolidone, polydimethylacrylamide, polyacrylate, polymethacrylate, polyvinyl alcohol, or polyvinyl acetate;
second structure comprises an enhanced color conversion material, wherein the enhanced color conversion material includes a mixture of an emitting material and a scattering material;
the emitting material includes one or more of: carbon nanoparticles, organic fluorophores, inorganic fluorophores, semiconductor nanoparticles, or perovskites;
the scatting material includes one or more of: metal particles or oxide particles;
the metal particles include one or more of: Ag, Au, Al, Cu, Pt, Cr, Ni, or their alloys; and
the oxide particles include one or more of: tin oxide, zinc oxide, titanium oxide, or indium oxide.
